(19) United States
(12) Patent Application Publication
(10) Pub. No.: US 2026/0220339 A1
(43) Pub. Date: Jul. 30, 2026

(54) Method for Identifying Parameter Distributions to Model a Technical System

(71) Applicant: Robert Bosch GmbH, Stuttgart (DE)

(72) Inventors: Kevin Schmidt, Herrenberg (DE); Nicola Henkelmann, Vaihingen/Enz (DE)

(21) Appl. No.: 19/453,385

(22) Filed: Jan. 20, 2026

(30) Foreign Application Priority Data
Jan. 22, 2025 (EP) 25153223.0

(51) Int. Cl. G06F 30/27

(52) U.S. Cl. CPC G06F 30/27

(57) ABSTRACT

A method for identifying parameter distributions for modeling a technical system includes (i) determining a nominal parameter estimate based on provided measurement data and at least one specified model of system dynamics of the technical system, (ii) determining a distribution of parameter changes based on a quantification of a parameter-related uncertainty of the nominal parameter estimate, and (iii) providing the nominal parameter estimate and the distribution of the parameter changes as the basis for modeling the technical system while taking into account the parameter-related uncertainty.

The invention relates to a method for identifying parameters for modeling a technical system. The invention further relates to a computer program, a device, and a storage medium for this purpose.

### PRIOR ART

Determining system parameters is a key element of model-based design. It is of great importance how well the model can describe reality. Many statements, such as performance guarantees, safety statements, compliance with limitations, failure probabilities and the like, depend substantially on this.

Consequently, some methods are already known from the prior art, which deal with the identification of system parameters based on measured data. Typically, only a nominal set of parameters is determined that represents the solution of an optimization problem. However, the remaining uncertainty is often not, or only implicitly, taken into account, although it is relevant to many downstream decisions.

Furthermore, inverse “uncertainty quantification” methods use Bayesian statistics to determine distributions of parameters. These methods may be implemented in the context of “probabilistic programming”. The application requires a high level of expertise. Further requirements for implementing the model further restrict usability. Applying these methods is associated with considerable time and cost and is difficult to integrate into an existing model identification process.

### DISCLOSURE OF THE INVENTION

The subject matter of the invention is a method having the features of claim 1, a computer program having the features of claim 9, an apparatus having the features of claim 10, and a computer-readable storage medium having the features of claim 11. Further features and details of the invention result from the respective dependent claims, the description and the drawings. Features and details which are described in connection with the method according to the invention naturally also apply in connection with the computer program according to the invention, the device according to the invention, and the computer-readable storage medium according to the invention, and vice versa in each case, so that a reciprocal reference is always possible with regard to the disclosure of the invention.

The subject matter of the invention is in particular a method for identifying parameters and/or parameter distributions and/or for uncertainty quantification and/or for modeling a technical system.

The method may comprise determining a nominal parameter estimate based on provided measurement data and at least one specified model of system dynamics of the technical system.

Furthermore, the method may comprise determining a distribution of parameter changes (or a stochastic component) based on a quantification of a parameter-related uncertainty of the nominal parameter estimate.

Moreover, the method may comprise providing the nominal parameter estimate and the distribution of the parameter changes as the basis for modeling the technical system, taking into account the parameter-related uncertainty.

According to the invention, the advantage can be achieved that a model of the technical system can be provided that takes into account both the nominal parameter values and their uncertainties. This enables more accurate and reliable modeling of the system as potential fluctuations in the parameters are captured. The consideration of uncertainties in the model leads to more robust control strategies and improved reliability of the technical system, particularly in applications with high requirements, such as in the automotive field.

According to the present invention, a two-step approach for identifying more reliable model parameters is proposed. In a first step, the nominal error between the available data and the model may be minimized without taking uncertainties into account. The remaining model uncertainty around this estimate may then be characterized via a linearized Bayesian approach.

Compared to conventional non-linear Bayesian methods, the estimates obtained according to the invention may be more conservative, if necessary, due to linearization. However, there are also significant advantages, which are explained further below.

Thus, the invention may offer the advantage that no preconditions for a particular model structure need to be met. As the model interface, only the specification of the input variables, the parameters to be identified, and reading out the corresponding system response may be required. Thus, the method may be applied to complex numerical models without requiring an analytical description.

Additional structural assumptions allow for an efficient evaluation of the required linearization and Bayesian regression. The latter allows use of the technical system considered at run time.

Bayesian statistics may further be encapsulated to allow broad applicability without explicit expert knowledge. The use of second-order statistics, i.e., the parameters are described internally by a mean and a (co-)variance, enables a closed-form solution of the linearized Bayesian regression problem.

The resulting linearization errors may further be quantified and considered in the design as part of the model uncertainty.

Furthermore, existing nominal parameter estimates may be integrated into the method. These may be confirmed, improved or discarded in the context of the invention.

One possible application of the invention is, for example, system identification for vehicle models used for vehicle lateral control, longitudinal control, driving dynamics regulation or component development.

In addition, it is advantageous if the method for identifying the parameters in the form of model parameters of a closed control loop is employed for vehicle control and preferably lateral vehicle guidance. Thus, the proposed parameter identification solution may be applied directly in real-world vehicle systems, for example, to more precisely model the behavior of the vehicle when cornering, thus improving stability and safety.

Furthermore, it may be contemplated within the scope of the invention that the method is provided for identification of the parameters for vehicle models that are preferably employed for lateral vehicle guidance and/or longitudinal vehicle guidance and/or driving dynamics regulation and/or component development and/or steering regulation and/or braking regulation. In particular, this will result in the method enabling improved identification of parameters and/or parameter distributions in various areas of vehicle technology.

Optionally, it is conceivable that the method is employed for investigating transference of a desired curvature of a vehicle trajectory onto an actual curvature of the vehicle trajectory, wherein the following steps are provided:
providing the specified model in the form of a model of a closed control loop for vehicle lateral guidance, and/or
performing the nominal parameter estimate to make a first estimate of at least one parameter of the model based on the provided measurement data, and/or
performing the quantification of the parameter-related uncertainty, which provides a remaining uncertainty in the estimated parameters, and/or
performing the determination of the distribution of parameter changes based on the quantification performed, and/or
performing the modeling of the technical system based on the nominal parameter estimate and the distribution of parameter changes, and/or
adjusting a control specification for vehicle lateral guidance based on the modeling.

Thus, the method may be used to determine parameters and/or parameter distributions that affect transference of the desired curvature of a vehicle trajectory to the actual curvature. The modeling of the system, taking into account the uncertainties in the parameters, allows an adjustment of the control specification for lateral vehicle guidance in order to achieve more accurate behavior and to increase safety.

Also, it is optionally conceivable that determining the nominal parameter estimate comprises: minimizing a nominal error between the provided measurement data and the specified model, in particular without taking into account uncertainties. In other words, the calculation of the nominal parameter value comprises minimizing a minimum deviation value between the available measurement data, in particular measured values, and the model.

According to an advantageous further development of the invention, it may be provided that determining the distribution of parameter changes comprises: characterizing the parameter-related uncertainty in the form of a model uncertainty remaining from the nominal parameter estimate. This allows a quantitative assessment of the influence of individual parameters on the system behavior.

According to another possibility, it can be provided that the determination of the distribution and in particular the characterization of the parameter-related uncertainty is performed by means of a linearized Bayesian approach. In other words, the method may preferably use a linear approximation of the system to characterize the parameter distribution.

Optionally, it is conceivable that the modeling of the technical system, while taking into account the parameter-related uncertainty, comprises consolidating the nominal parameter estimate and the distribution of parameter changes into a total estimate. In other words, the nominal parameter estimate and the distribution of parameter changes are preferably combined to obtain a comprehensive estimate of the system, taking into account both the mean and the uncertainty of the parameters. This allows a more realistic and robust model of the technical system.

It is possible for the method according to the invention to be used in a vehicle. The vehicle can be designed, for example, as a motor vehicle and/or passenger vehicle and/or at least partially automated/autonomous vehicle. The vehicle may have a vehicle device, for example, for providing an autonomous driving function and/or a driver assistance system. The vehicle device may be configured to control the vehicle at least partially automatically and/or to accelerate and/or brake and/or steer.

Another object of the invention is a computer program, in particular a computer program product, comprising instructions which, when the computer program is executed by at least one computer, cause the computer to carry out the method according to the invention. The computer program according to the invention thus brings about the same advantages as have been described in detail with reference to the method according to the invention.

The subject matter of the invention is also a device for data processing that is configured to execute the method according to the invention. The device can be at least one computer, for example, that executes the computer program according to the invention. The computer may have at least one processor for executing the computer program. A non-volatile data memory can be provided as well, in which the computer program can be stored and from which the computer program can be read by the processor for execution.

The invention can also relate to a computer-readable storage medium, which comprises the computer program according to the invention and/or commands that, when executed by at least one computer, prompt said computer program to carry out the method according to the invention. The storage medium is configured, for example, as a data memory such as a hard disk and/or a non-volatile memory and/or a memory card. The storage medium may, for example, be integrated in the computer.

Furthermore, the method according to the invention may also be executed as a computer-implemented method. Alternatively or additionally, at least one of the disclosed method steps may be computer-implemented and/or performed automatically.

Further advantages, features and details of the invention will be apparent from the following description, in which exemplary embodiments of the invention are described in detail with reference to the drawings. In this case, the features mentioned in the claims and in the description may in each case be essential to the invention individually or in any desired combination. They show:

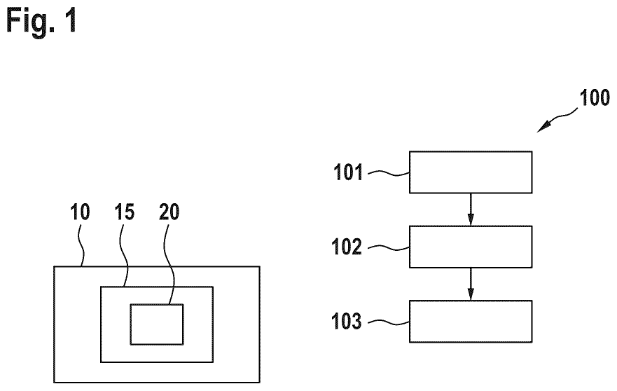

FIG. 1A schematic illustration of a method, a device, a storage medium and a computer program according to exemplary embodiments of the invention.

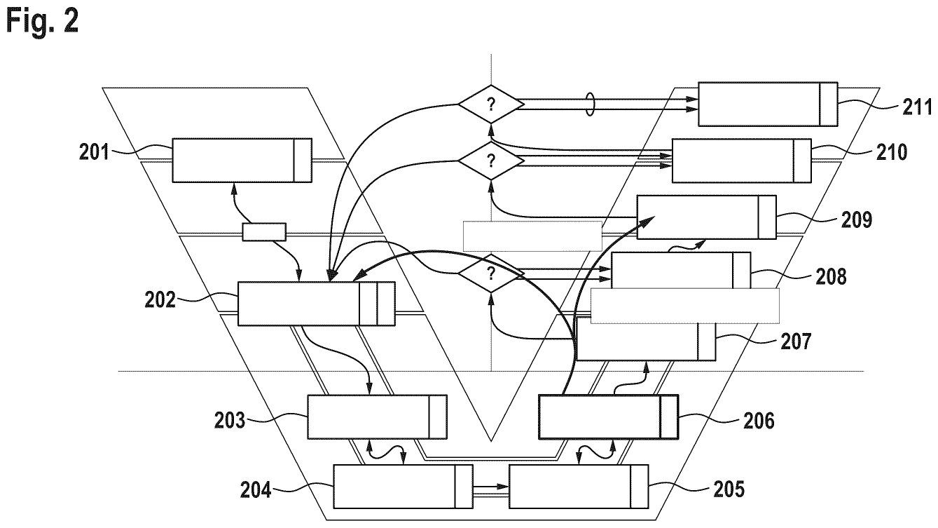

FIG. 2: An embedding of the system identification according to embodiments of the invention into the V-model.

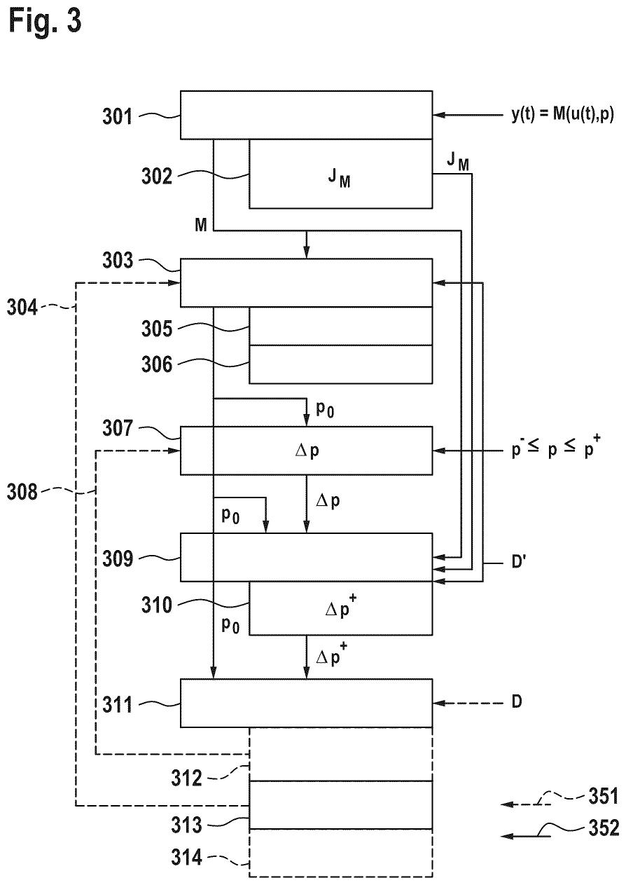

FIG. 3 An exemplary flow chart for identifying the parameters and their uncertainty according to embodiments of the invention.

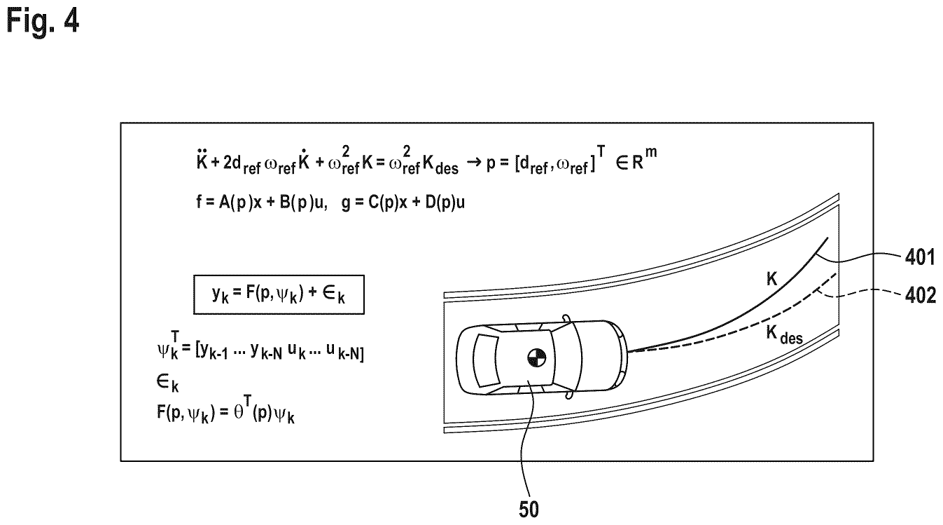

FIG. 4A visualization of the technical system as well as the problem which underlies embodiments of the invention.

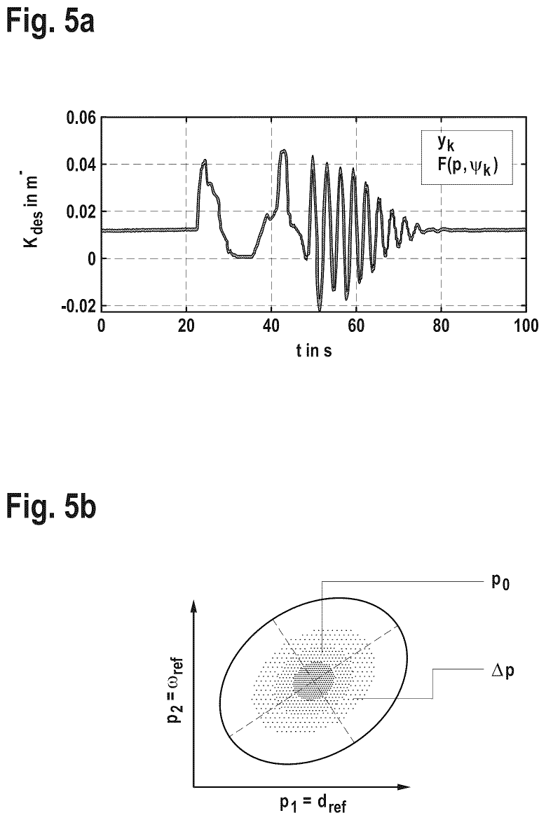

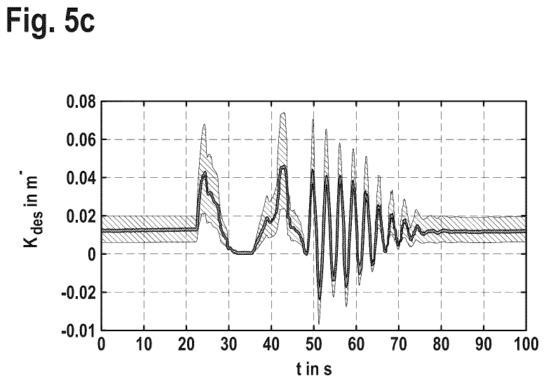

FIG. 5 Another exemplary visualization of the application of embodiments of the invention.

FIG. 1 schematically illustrates a method 100, a device 10, a storage medium 15, and a computer program 20 according to exemplary embodiments of the invention.

According to exemplary embodiments of the invention, the method 100 is provided for identification of parameters and/or parameter distributions for modeling a technical system 50. According to a first method step 101, a nominal parameter estimate is determined based on provided measurement data D and at least one specified model of the system dynamics of the technical system 50. The technical system 50 preferably relates to a vehicle, as will be discussed further below. The system dynamics can, for example, relate to lateral stiffness and/or vehicle parameters and/or environmental parameters and/or tire characteristics.

According to a second method step 102, a distribution of parameter changes is determined based on a quantification of a parameter-related uncertainty of the nominal parameter estimate. In particular, a distribution is determined for a stochastic component.

According to a third method step 103, the nominal parameter estimate and the distribution of the parameter changes are provided as the basis for modeling the technical system 50, taking into account the parameter-related uncertainty. In other words, modeling may be performed based on the results of the preceding method steps 101 and 102.

Variations of the invention may be a central component of system identification (see, for example, 206 in FIG. 2), so that, in other words, modeling may be used for system identification of a technical system 50.

In FIG. 2, a V-model is shown that illustrates various stages and processes in the development cycle. The individual steps are named as follows:

Step 201 describes the collection and definition of requirements (“Requirements”). Then, in step 202, the system design (“System Design”) is carried out, followed by the definition of the system sample in step 203 (“System Sample Definition”). In the next step, step 204, the system sample is set up (“System Sample Setup”). Thereafter, in step 205, the measurements take place on the system (“System Measurements”). Based on these results, a credible system model is created in step 206 (“Credible System Model”), which in turn is verified and validated in step 207 by simulations (“Verification & Validation by Simulation”).

The practical validation is then carried out in several stages: Step 208 includes the actual system sample (“System Sample”), followed by laboratory tests in step 209 (“Validation by Lab Tests”) and real-world tests in step 210 (“Validation by Real-World Tests”). Finally, in step 211, the OEM tests are performed (“OEM Tests”).

Often, not only a nominal parameter set is to be determined based on the system measurements 205, but also its uncertainty is to be characterized using a stochastic distribution. This information can be utilized in the left-hand path of the V-model (system synthesis comprising 201 and 202) to achieve a balance between performance and robustness of control functions. This may be done at design time or at run time. In the right-hand path of the V-model (system analysis comprising 207-211), the characterized uncertainty may be used for release argumentation based on reliable models.

Variations of the invention are broken down into five important steps, the technical background of which will be explained in more detail below. The steps are shown with further details in FIG. 3.

In FIG. 3, 301 denotes the processing of the system model, 302 a mechanism for calculating linearization [symbol] , 303 the nominal identification, 304 the operation in which the nominal identification is updated, if applicable, 305 the optimization problem, 306 the numerical solver, 307 the construction of an a-priori estimate for Δp, 308 the operation in which the a-priori estimate is updated, if applicable, 309 the linearized Bayesian regression, 310 the calculation method for the a-posteriori distribution

$${Δ}_{p}^{+} ,$$

311 the result and the application, 312 applying the algorithm to the next or a new data packet, 313 reviewing the outcome, and 314 the creation of the surrogate model. Furthermore, 351 indicates optional and 352 externally required paths.

The basic idea for determining a credible parameter estimate in the context of exemplary embodiments of the invention starts with the decomposition

$$p = {p}_{0} + Δ p \qquad ( 1 )$$

p₀ is the result of a nominal identification 303 without consideration of uncertainties and is the focus of step 2. Based on this, the determination of the stochastic component Δ takes place, which makes it possible to determine confidence intervals for the parameters and the output variables.

### System Model.

According to step 301 in FIG. 3, the starting point is a system model, i.e., a model of the technical system 50 that establishes the structural relationship between parameters to be identified, a given system stimulation ( ), and output variables ( ) corresponding to the measured variables:

$$y ( t ) = ℳ ( u ( t ) , p ) . \qquad ( 2 )$$

The model typically has additional internal state variables ( ) and is in the form of a differential equation system:

$$\dot{x} ( t ) = f ( x ( t ) , u ( t ) , p ) y ( t ) = g ( x ( t ) , u ( t ) , p ) \qquad ( 3 )$$

In the following sections, the time series of the input and output variables

$$D = {\{ {\overline{u}}_{k} , {\overline{y}}_{k} \}}_{{k}_{0} \leq k \leq {k}_{f}}$$

are assumed as measurement data. A constant sampling time is used to simplify the notation

$$h > 0 mit {y}_{k} = y ( {t}_{k} )$$

$$and$$

$${t}_{k} = k h$$

Measurement signals aggregated into vectors or matrices are denoted by capital letters Ū and Y̅.

Variations of the invention require the partial derivative ∂ [symbol] M/∂p of the model with respect to the parameters in the proximity of a fixed value p₀. This can be done numerically, for example, via a finite difference method, provided the model is not in analytical form. To avoid implicit differentiations, it is appropriate to convert the model [symbol] to an input-output representation of the form

$$ℳ : {y}_{k} = F ( p ; \underbrace{{y}_{k - 1} , … {y}_{k - N} , {u}_{k} , … , {u}_{k - M}}_{{ψ}_{k}} ) = F ( p , {ψ}_{k} ) \qquad ( 4 )$$

The transition to a time-discrete representation has the advantage that the internal state variables can be replaced by past values of the inputs and outputs, which are directly present in the data [symbol] . The partial derivative of the model required at a given point p₀ is thus determined as follows:

$${{J}_{ℳ} ( {u}_{k} , {p}_{0} ) = \frac{\partial F ( p ,}{\partial p} \vert}_{p = {p}_{0}} . \qquad ( 5 )$$

Due to the memory characteristic of the model [symbol] that is not explicitly apparent in (1), the value of the Jacobian matrix also depends on the previous input and output values, as can be seen in (4).

### General Case (Numeric Approximation):

An approximation of the Jacobian matrix ∂ [symbol] /∂p is carried out here by a numerical method, e.g. finite differences. The number of evaluations required of the model (2) will depend on the number of parameters and the output variables.

### Special Case 2 (Sensitivity ODE):

Here, the model is in the form of analytical functions (3) and the current value of the Jacobian matrix [symbol] can be determined via sensitivity differential equations with =/. The following connection results from the application of the chain rule:

$${{{J}_{ℳ} ( {u}_{k} , {p}_{0} ) = \frac{\partial g}{\partial p} \vert}_{( {x}_{k} , {u}_{k} , {p}_{0} )} + \frac{\partial g}{\partial x} \vert}_{( {x}_{k} , {u}_{k} , {p}_{0} )} S ( {t}_{k} )$$

$${{{\dot{S} ( {t}_{k} ) = \frac{\partial f}{\partial x} \vert}_{( {x}_{k} , {u}_{k} , {p}_{0} )} S ( {t}_{k} ) + \frac{\partial f}{\partial p} \vert}_{( {x}_{k} , {u}_{k} , {p}_{0} )} , {t}_{k} > {t}_{0} , S ( {t}_{0} ) = \frac{\partial {x}_{0}}{\partial p} \vert}_{{p}_{0}}$$

To calculate the temporal progression of the Jacobian matrix [symbol] at the required time points tₖ, a dynamic system must thus be co-simulated in addition to (3). Further evaluations of the model, as in the general case, are not necessary.

### Special Case 1 (LPV System):

In the case of linear dynamics with nonlinear parameter interventions with

$$f = A ( p ) x + B ( p ) u and g = C ( p ) x + D ( p ) u ,$$

a closed relationship for the input-output model (4) can be derived over the discrete-time image domain. Using the zero-order hold method as an example, the discrete-time transfer function follows

$$G ( {z}^{- 1} ) = \frac{adj ( {C ( p ) [ I - {e}^{Λ ( p ) h} {z}^{- 1} ]}^{- 1} {\int }_{0}^{h} {e}^{Λ ( p ) t} dtB ( p ) {z}^{- 1} + D ( p ) )}{det ( {C ( p ) [ I - {e}^{Λ ( p ) h} {z}^{- 1} ]}^{- 1} {\int }_{0}^{h} {e}^{Λ ( p ) t} dtB ( p ) {z}^{- 1} + D ( p ) )} = \frac{{b}_{0} ( p ) + {b}_{1} ( p ) {z}^{- 1} + … + {b}_{N} ( p ) {z}^{- M}}{1 + {a}_{1} ( p ) {z}^{- 1} + … + {a}_{N} ( p ) {z}^{- N}} . \qquad ( 6 )$$

which is a fractional rational polynomial in the image variable Z⁻¹. Thus, (6) in the time domain corresponds to the difference equation

$${y}_{k} = {\sum }_{n = 1}^{N} {a}_{n} ( p ) {y}_{k - n} + {\sum }_{n = 0}^{M} {b}_{n} ( p ) {u}_{k - n} = \underbrace{[ {a}_{1} … {a}_{N} , {a}_{1} … {a}_{N} ] ( p )}_{{θ}^{T} ( p )} \underbrace{[ \begin{matrix}{y}_{k - 1} \\ ⋮ \\ {y}_{k - N} \\ {u}_{k} \\ ⋮ \\ {u}_{k - M}\end{matrix} ]}_{{ψ}_{k}} = {θ}^{T} ( p ) {ψ}_{k} . \qquad ( 7 )$$

This enables an efficient and analytical calculation of the required Jacobian matrix from (5) using the rule

$${{J}_{ℳ} ( {u}_{k} , {p}_{0} ) = {J}_{θ}^{T} ( {p}_{0} ) {ψ}_{k} and {J}_{θ} ( {p}_{0} ) = d θ ( p ) / dp \vert}_{{p}_{0}} .$$

### 2. Nominal Identification.

The identification of a nominal parameter set for a given model (1) and data [symbol] is possible using known prior art methods; see, among others, Ljung, Lennart. “System identification.” Signal analysis and prediction. Boston, MA: Birkhäuser Boston, 1998, and Bishop, Christopher, and Nasser Nasrabadi. Pattern recognition and machine learning. NY: Springer, 2006.

The goal is to minimize an error measure Q(e)∈ [symbol] between measurement data and data that is specified by the residual eₖ(p)=y̅ₖ− [symbol] (ūₖ, p). For the complete considered data set, the error vector and the optimal nominal parameter set are obtained as

$${p}_{0} = arg {min}_{p} Q ( e ) . \qquad ( 8 )$$

### Special Case:

The method is not limited to a specific algorithm for determining p₀. The choice of a maximum likelihood or maximum a-posteriori estimator (ridge regression) offers advantages in combination with the linearized Bayesian regression from step 4.

Depending on the regularization parameter ≥0, the nonlinear optimization problem results.

$${p}_{0} = arg {min}_{p} Q = {[ \overline{Y} - F ( p , \overline{Ψ} ) ]}^{T} [ \overline{Y} - F ( p , \overline{Ψ} ) ] + λ {p}^{T} p . \qquad ( 9 )$$

3. Construction of an a-Priori Estimate.

For the application of Bayesian regression, the construction of an a-priori distribution is necessary for the stochastic component Δ. A distinction must be made as to whether the algorithm is used initially or iteratively. For the initialization of the distribution, the exemplary choice

$$Δ p ∼ 𝒩 ( {μ}_{p} , {\sum }_{p} ) mit {μ}_{p} = 0 , \qquad ( 10 )$$

The method is not limited to a particular distribution assumption for the a-priori distribution. However, the approach (10) subsequently allows a closed-form solution of the Bayesian regression problem and thus makes an application at run time possible. The covariance Σₚ in (10) can either be constructed directly from known standard deviations

$${\sum }_{p} = diag ( {σ}_{p , i}^{2} )$$

or from known (physical) boundaries

$${p}^{-} \leq p \leq {p}^{+} mit {\sum }_{p} = \frac{1}{12} {diag ( {p}^{+} - {p}^{-} )}^{2}$$

If the algorithm has already been run for part of the available data or if new data is present in the meantime, the a-posteriori estimates from step 4 may be used as new a-priori estimates, i.e.

$${\sum }_{p} ← {\sum }_{p}^{+} .$$

The mean may either be set to

$${μ}_{p} ← {μ}_{p}^{+}$$

or the mean value is taken into account in the deterministic component

$$( {p}_{0} ← {p}_{0} + {μ}_{p} und {μ}_{p} = 0 ) .$$

The latter corresponds to an update of the linearization point and is possibly associated with the re-evaluation of the Jacobian matrix (5).

### 4. Linearized Bayesian Regression.

The basis for the Bayesian regression of the remaining component Δ of the parameters to be identified is the residual error, which remains 0 despite the nominal parameter estimate. In order to obtain a linear regression problem, the model linearized around the point 0 is used:

$${y}_{k} = ℳ ( {u}_{k} , {p}_{0} ) + {J}_{ℳ} ( {u}_{k} , {p}_{0} ) Δ p + {ε}_{k} \qquad ( 11 )$$

$${ε}_{k} ∼ 𝒩 ( 0 , {β}^{- 1} )$$

is an error term that accounts for the measurement noise with variance

$${σ}_{y}^{2}$$

and the confidence in the model is represented via the precision parameter

$${β}^{- 1} = {σ}_{y}^{2} + {σ}_{m odel}^{2}$$

The latter can also take into account the linearization error via the standard error σ_{model} The resulting regression problem is

$${\overline{y}}_{k} - ℳ ( {\overline{u}}_{k} , p ) = {J}_{ℳ} ( {p}_{0} ) Δ p ⇔ {e}_{k} = {J}_{ℳ} ( {p}_{0} ) Δ p \qquad ( 12 )$$

Application of Bayes' theorem provides the following relationship between the a-priori distribution p(Δp′ [symbol] ′,β) given a (sub-)dataset [symbol] ′={Ū′,Y̅′} and the a-posteriori distribution

$$Δ {p}^{+} ∼ Pr ( {y}_{k} \vert Δ p , {𝒟}^{′} , β ) = \int Pr ( {y}_{k} \vert Δ p ) Pr ( Δ p \vert {𝒟}^{′} , β ) d ( Δ p ) . \qquad ( 13 )$$

Numerical approximation is possible for general distribution forms. Since the algorithm can also be used recursively, at this point a distinction is explicitly made between the entire dataset [symbol] and the dataset [symbol] ′ This means that not all available data must be used, or the existing estimate can be expanded with new data.

However, for choice (7), a normal distribution results from (13)

$$Δ {p}^{+} ∼ 𝒩 ( {μ}_{p}^{+} , {\sum }_{p}^{+} )$$

with closed-form solution

$${μ}_{p}^{+} = {\sum }_{p}^{+} ( {\sum }_{p}^{- 1} {μ}_{p} + β {J}_{ℳ}^{T} ( {\overline{U}}^{′} , {p}_{0} ) [ {\overline{Y}}^{′} - ℳ ( {\overline{U}}^{′} , {p}_{0} ) ] ) {( {\sum }_{p}^{+} )}^{- 1} = {\sum }_{p}^{- 1} + β {J}_{ℳ}^{T} ( {\overline{U}}^{′} , {p}_{0} ) {J}_{ℳ} ( {\overline{U}}^{′} , {p}_{0} ) . \qquad ( 14 )$$

For the special case 2 of the system representation shown in (6)-(7),

$${μ}_{p}^{+} = {\sum }_{p}^{+} ( {\sum }_{p}^{- 1} {μ}_{p} + β {\overline{Ψ}}^{′ , T} {J}_{θ} ( {p}_{0} ) [ {\overline{Y}}^{′} - {θ}^{T} ( {p}_{0} ) {\overline{Ψ}}^{′} ] ) {( {\sum }_{p}^{+} )}^{- 1} = {\sum }_{p}^{- 1} + β {J}_{θ}^{T} ( {p}_{0} ) [ {\overline{Ψ}}^{′} {\overline{Ψ}}^{′ , T} ] {J}_{θ} ( {p}_{0} ) , \qquad ( 15 )$$

which allows a direct evaluation, i.e., without numerical sampling, of the a-posteriori distribution. The calculation of the a-posteriori distribution (13) reduces to matrix-vector multiplications, since the Jacobian matrices J̅θ(p₀) can be pre-calculated.

### 5. Result & Application.

The final step of embodiments of the invention brings both parts of the total estimate back together and consolidates p₀ from step 2 and Δp from step 4 into the total estimate.

Depending on the situation, this may include the following aspects:

The assumption of linearization implies that the mean of the Bayesian a-posteriori distribution should be small in comparison to p₀, i.e.

$${μ}_{p}^{+} ≪ {p}_{0} .$$

If this is not the case, this is an indication of an estimate in need of improvement in step 2ff, i.e., the optimization problem should be adapted, for example by adjusting the regularization parameter in (9) or the precision parameter in the regression problem (11).

A further indication is the significant deviation of the measured data from a suitable confidence interval. The choice λ=t(τp)/β also represents a consistent parameterization of both steps. Where t may be selected as a trace operator and may refer to the a-priori variance Σₚ or the a-posteriori variance

$${\sum }_{p}^{+} .$$

As described in step 3, embodiments of the invention may be applied recursively to sub-data sets ′. If this is the case, the next data section can be selected here, and the previous steps are repeated. This also includes execution at run time, i.e., if new data has been collected since the last invocation, the algorithm may be run again.

For certain model structures, it is possible to generate a deterministic surrogate model from the identified parameter distributions. Known methods may be used for this purpose. The resulting model with identified parameter distributions may then be applied to the following applications: Synthesis or update of a control algorithm at design time or run time, sensitivity analysis or reliability analysis in the verification & validation.

Optimal input signals are determined by the above steps.

If a nominal estimate is already known, step 2 “nonlinear identification” may be omitted. In this case, 0 must be specified externally or by the user.

Variations of the invention may be used in any technical context based on a model-based control function and/or verification based on reliable models. The initial use case is to identify the model parameters for a vehicle model of lateral dynamics.

Another application is the identification of the longitudinal guidance behavior of vehicles, the steering regulation (e.g., rack position regulation) or the brake control loop of vehicles (e.g., ESP, decoupled/integrated power brake, by-wire actuator, etc.). Further obvious application cases are driving dynamics regulation, (large-area) robotics or the regulation of electrical machines.

An important embodiment is the identification of a closed control loop for lateral vehicle guidance. Further details are shown in FIG. 4 for this purpose. In this case, a path model is used, which is sufficient for the special case 1 of step 1. The objective is to investigate the transfer behavior from the desired curvature 402 of the vehicle trajectory to the actual curvature 401. Based on the existing measurement data (see FIG. 5a), as part of step 2 of the invention, a nominal parameter estimate 0 can be determined that describes the essential behavior. The remaining uncertainty is quantified by the distribution of A from step 4. The resulting distribution can be represented in the parameter space (see FIG. 5b) or as a confidence interval of the system output (see FIG. 5c).

The foregoing explanation of the exemplary embodiments describes the present invention exclusively in the context of examples. Of course, individual features of the embodiments can be freely combined with one another, if technically feasible, without leaving the scope of the present invention.

1. A method for identifying parameter distributions for modeling a technical system, comprising:
determining a nominal parameter estimate based on provided measurement data and at least one specified model of system dynamics of the technical system,
determining a distribution of parameter changes based on a quantification of a parameter-related uncertainty of the nominal parameter estimate, and
providing the nominal parameter estimate and the distribution of the parameter changes as the basis for modeling the technical system while taking into account the parameter-related uncertainty.

2. The method 1 according to claim 1, wherein the method is employed for identifying the parameters in the form of model parameters of a closed control loop for vehicle control and vehicle lateral guidance.

3. The method 1 according to claim 1, wherein the method is provided for identification of the parameters for vehicle models that are employed for vehicle lateral guidance and/or vehicle longitudinal guidance and/or vehicle dynamics regulation and/or component development and/or steering regulation and/or braking regulation.

4. The method 1 according to claim 1, wherein the method is employed for investigating a transfer behavior from a desired curvature of a vehicle trajectory to an actual curvature of the vehicle trajectory, wherein the following steps are provided:
providing the specified model in the form of a model of a closed control loop for vehicle lateral guidance,
performing the nominal parameter estimate to make a first estimate of at least one parameter of the model based on the provided measurement data,
performing the quantification of the parameter-related uncertainty, which provides a remaining uncertainty in the estimated parameters,
performing the determination of the distribution of parameter changes based on the quantification performed,
performing the modeling of the technical system based on the nominal parameter estimate and the distribution of parameter changes, and
adjusting a control specification for vehicle lateral guidance based on the modeling.

5. The method 1 according to claim 1, wherein determining the nominal parameter estimate comprises:
minimizing a nominal error between the provided measurement data and the specified model without taking into account uncertainties.

6. The method 1 according to claim 1, that wherein determining the distribution of parameter changes comprises:
characterizing the parameter-related uncertainty in the form of a model uncertainty remaining from the nominal parameter estimate.

7. The method 1 according to claim 1, wherein the determination of the distribution, and the characterization of the parameter-related uncertainty, is performed using a linearized Bayesian approach.

8. The method 1 according to claim 1, wherein the modeling of the technical system, while taking into account the parameter-related uncertainty, comprises consolidating the nominal parameter estimate and the distribution of parameter changes into a total estimate.

9. A computer program, comprising commands which, when the computer program is executed by at least one computer, cause the latter to execute the method according to claim 1.

10. A device for data processing, configured to carry out the method according to claim 1.

11. A computer-readable storage medium, comprising instructions which, when executed by at least one computer, cause the computer to carry out the steps of the method according to claim 1.
